(19) United States
(12) Patent Application Publication
(10) Pub. No.: US 2016/0351259 A1
(43) Pub. Date: Dec. 1, 2016

(54) MEMRISTOR MEMORY

(71) Applicant: HEWLETT PACKARD ENTERPRISE DEVELOPMENT LP, Houston, TX (US)

(72) Inventors: Yoocharn Jeon, Palo Alto, CA (US); Erik Ordentlich, San Jose, CA (US); Gregg B. Lesartre, Fort Collins, CO (US); Siamak Tavallaei, Spring, TX (US)

(21) Appl. No.: 15/111,981

(22) PCT Filed: Jan. 24, 2014
(86) PCT No.: PCT/US2014/013011

§ 371 Date: Jul. 15, 2016

(51) Int. Cl. G11C 13/00; G06F 11/10; G11C 29/52; G11C 29/12

(52) U.S. Cl. CPC G11C 13/0069; G11C 13/004; G11C 13/0007; G11C 13/0064; G11C 29/12; G06F 11/1068; G11C 29/52; G11C 2013/0076

(57) ABSTRACT

A memristor memory is disclosed. In an example, the memristor memory comprises a memristor component having a plurality of memristor cells. Each memristor cell is configured to change state based on application of an electric potential. The memristor memory also comprises a controller to read the state of the plurality of memristor cells and identify a subset of the plurality of memristor cells to rewrite. The controller writes the subset of the plurality of memristor cells, and the controller reads an updated state of the plurality of memristor cells to validate the subset was written correctly.

### BACKGROUND

The memristor (“memory resistor”) was originally envisioned in 1971 by Leon Chua. Chua started by explaining the fundamental circuit elements: the resistor, capacitor, and inductor. Chua then proved that no combination of the other fundamental circuit elements (i.e., resistors, capacitors and inductors) could duplicate the properties of a memristor. This inability to duplicate the properties of a memristor with the other passive circuit elements makes the memristor another fundamental circuit element.

In 2008, a team at Hewlett-Packard (HP) Labs published the results of an analysis of a thin film of titanium dioxide made to behave as a memristor device. HP Labs went on to create an elementary circuit model that was defined by the same mathematical equations as those predicted by Chua for the memristor. The team then showed that this simple model could reproduce a wide variety of complex current-voltage (I-V) curves. The team also showed the equations for the drift of oxygen vacancies in titanium dioxide, and their influence on the electronic conduction in the material, were also identical with an equivalent circuit model, and thus the memristor equations.

From this, it was possible to develop a formula for the memristance of a device. This memristance formula showed that the size of the most important term in the memristance equations gets larger as the device size decreases. As such, understanding memristance is even more important as the size of circuits continue to get smaller. This is particularly true when designing electronic circuits in the realm of nano-size electronics.

### BRIEF DESCRIPTION OF THE DRAWINGS

FIGS. 1a-b illustrate an example memristor memory.

FIG. 2 is a plot illustrating operational states of an example memristor memory.

FIGS. 3a-b illustrate an example of read-before-write operations of a memristor memory.

FIGS. 4a-b illustrate another example of read-before-write operations of a memristor memory.

FIGS. 5a-b illustrate another example of read-before-write operations of a memristor memory.

FIG. 6 is a flow chart illustrating example read-before-write operations which may be implemented by a memristor memory.

FIG. 7 is a flow chart illustrating example verification operations using an error correction code.

FIG. 8 is a flow chart illustrating example operations to constrain a number of memristor cells that can change during overwrite.

### DETAILED DESCRIPTION

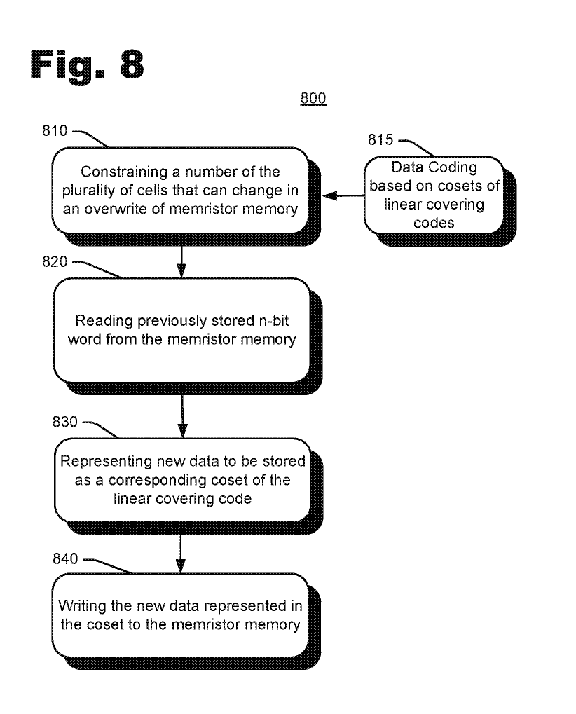

A memristor memory is disclosed herein. The memristor memory exhibits properties of memristance, including a dynamic relationship between current and voltage. The most recognizable signature of a memristor is that when an AC voltage is applied to the device, the current-voltage (I-V) plot is that of a Lissajous figure (the curve formed by combining two oscillations that are perpendicular to each other). The most commonly observed I-V trace is a ‘figure 8’, or a ‘pinched loop’ for which the current is zero when the voltage is zero. The memristor memory also exhibits a “memory” of past voltages or currents, thus has particular application in the non-volatile memory space.

Memristor that can be fashioned into non-volatile memory devices enable greater data density than hard drives, with access times similar to dynamic random access memory (DRAM). For example, a crossbar based memristor memory can fit 100 gigabits in a square centimeter, and a scalable three dimensional design with up to 1000 layers or 1 petabit per cm³. Access times can he as high as 90 nanoseconds, if not faster. This is approximately one hundred times faster than contemporaneous flash memory, while using only one percent as much energy as flash memory.

Memristor-based devices operate by the movement of atoms, ions, vacancies, and/or impurities caused by the application of current/voltage exceeding a certain magnitude to change the state of the device (write and erase processes). Once these atomic motions are completed, the device state is determined (read) at lower currents and voltages.

A memristor exhibits a very long endurance when operated under normal or “optimal” switching conditions. But if the memristor is driven beyond safe operating limits (e.g., by applying too high a voltage or too long or too many biases), it can be difficult to restore the memristor with a regular switching pulse. This may also deteriorate the operational lifetime of the device.

In most memory operations new data are written into memory devices without checking the previously stored data. This practice is harmless when writing the same data content into a memory device that cannot be damaged by simple read/write operations (e.g., DRAM or SRAM). However, a memristor changes state based on generating an electric potential across the device structure. A higher voltage (or a longer bias) can damage the device structure. This is referred to as overdriving the memristor, and requires a higher voltage (or a longer bias) to return the memristor to a typical operating range. Overdriving may cause a subsequent write operation to fail, and over time may lead to device failure.

The memristor memory disclosed herein reduces the occurrence of overdriving during operation, and hence may reduce the occurrence of write failures and extend the usable life of the memristor memory. An example memristor memory includes a memristor component having a plurality of memristor cells. Each memristor cell is configured to change state based on application of an electric potential. For example, the plurality of memristor cells may be configured as an array (e.g., a memory array). Each memristor cell represents an individual memristor device structure. That is, each memristor cell is a two-terminal memristor device, The example memristor memory also includes a controller to read the state of the plurality of memristor cells. The controller may verify that a number of switching failures is no larger than what can be corrected by an error correction code (ECC).

In an example, a write operation is preceded by reading the data already stored in the memristor memory. New data is written only if the new data to be written is different from the data already stored. For example, if a logical “1” is to be written to a cell in the memristor memory, but that cell already contains a logical “1,” then there is no need to rewrite a logical “1” to that cell. Likewise, if a logical “0” is to be written to a cell in the memristor memory, but that cell already contains a logical “0,” then there is no need to rewrite a logical “0” to that cell. However, if the cell is in an opposite state (e.g., a “0” when a “1” is to be written, or vice versa), hen the state of the cell may be changed.

In another example, the written data is verified after the writing and/or by error detection and correction when the data is read at a later time. The controller rewrites erroneous memristor cells only if the number of switching failures is larger than what can be corrected by an error correction code. The controller verifies newly written data immediately after the newly written data is written to the plurality of memristor cells.

In another example, coding technique(s) may be implemented to constrain the number of memristor cells that change state during a write operation. The controller may constrain a number of the plurality of memristor cells that can change in an overwrite. The constrained number of the plurality of memristor cells may be based on data coding. The data coding may be based on cosets of linear covering codes.

These examples may be implemented alone and/or in combination with one or more of the other techniques. In any event, each of these examples help reduce deviation of the memristor memory from an optimal operating condition, by minimizing the number of times a memristor cell is written and/or reducing or altogether eliminating over-writing a memristor cell that already contains the value to be stored.

Before continuing, it is noted that as used herein, the terms “includes” and “including” mean, but are not limited to, “includes” or “including” and “includes at least” or “including at least.” The term “based on” means “based on” and “based at least in part on.”

In theory, an ideal memristor is defined as a passive two-terminal electronic device that is built to express only the property of memristance (just as a resistor expresses resistance and an inductor expresses inductance). Another way of describing a memristor is as any passive two-terminal circuit element that maintains a functional relationship between the time integral of current (called charge) and the time integral of voltage (often called flux, as it is related to magnetic flux). The slope of this function is called the memristance M, and is similar in some regards to variable resistance.

In practice, however, it may he difficult to build a ‘pure memristor,’ because an actual device may have a small amount of some other property, such as capacitance (just as an actual, non-theoretical inductor also exhibits resistance). Therefore, the term “memristor” is used herein to mean any device which exhibits properties of memristance, whether a ‘pure’ or theoretical memristor, or an actual device at least exhibiting some properties of memristance (although the device may also exhibit some amount of capacitance, resistance and/or inductance).

The definition of a memristor is based on the fundamental circuit variables of current and voltage and associated time-integrals (e.g., like the resistor, capacitor and inductor). But unlike these other three elements, which are allowed in linear time-invariant (LTI) system theory, memristors have a dynamic function with memory and may be described as some function of net charge. As such, to date there is no such thing as a “standard” memristor. Instead, each device implements a particular function, wherein the integral of voltage determines the integral of current, and vice versa.

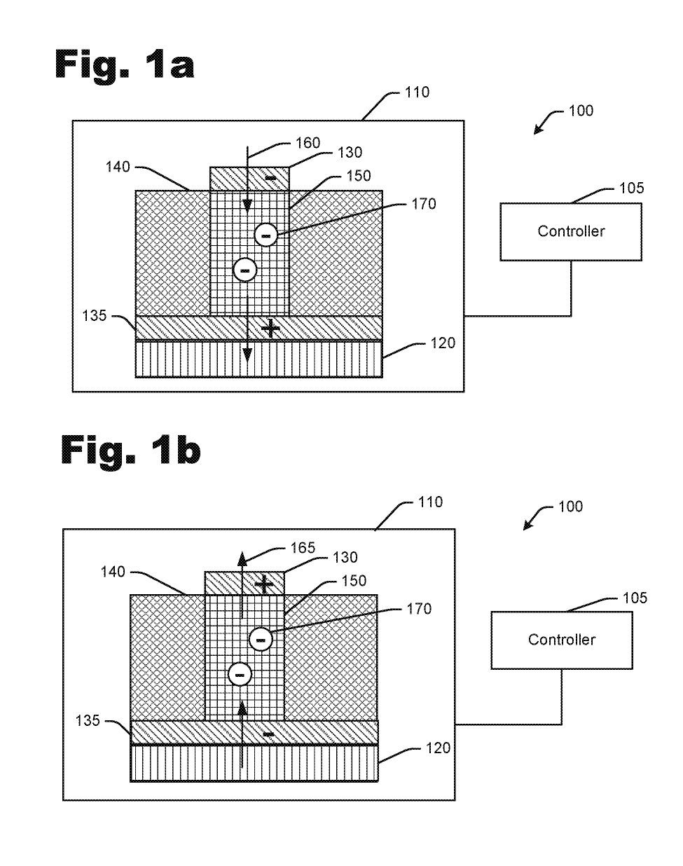

FIGS. 1a-b illustrate an example memristor memory 100. The memristor memory 100 may include a controller 105 operatively associated with a memristor element or “cell” 110. In an example, the controller 105 may be operatively associated with an individual memristor cell 110 on a one-to-one basis, e.g., as illustrated in FIGS. 1a-b. In another example, the controller 105 may be operatively associated with a plurality of memristor cells 110 (e.g., an array of cells 110). In another example, the controller 105 may include a plurality of controllers, such as individual controllers each associated with individual memristor cells 110 (e.g., on a one-to-one basis). In this example, the controller 105 may include or be further associated with a “master” controller which controls a plurality (e.g., “array” or “bank”) of controllers.

Each memristor cell 110 may be implemented as a memristor device structure. An example device structure is shown in FIGS. 1a-b. and includes a substrate 120, a first electrode 130, a second electrode 135, an insulator 140, and a channel 150 formed between the first and second electrodes.

In an example, the device structure is fabricated by deposition on the substrate 120, such as silicon. It is noted that in another example (not shown), the device structure may be fabricated by cutting a trench into the substrate 120. By deposition or implant doping, a “bottom” metal or degenerately doped electrode 135 is formed to inject or remove charges from the channel 150. The channel 150 is fabricated by additive deposition of a material, such as but not limited to transition metal oxides (e.g., Ta, Ti). Other suitable materials may also be appropriate. In another example, the channel 150 may be fabricated by diffusively doping a sidewall of the trench (not shown) with the transition metal oxide and/or other suitable material.

An insulating charge barrier 140 (e.g., silicon nitride, aluminum oxide. SiO₂) is then deposited. In another example, the charge barrier 140 may be thermally grown on the sidewall of the trench (not shown). A top electrode 130 is fabricated on top of the channel 150 to complete the device structure.

It is noted that the terms “top” and “bottom” are used with reference to the deposition layers, with bottom layers being deposited first, and “top” layers being deposited over the “bottom” layers. While these terms are illustrative with reference to the figures, and may be useful during fabrication, the terms “top” and “bottom” are not intended to be limiting of the device structure in any manner.

It is noted that any suitable fabrication processes may be implemented to manufacture the device structure. For example, fabrication techniques may be similar to those used to produce titanium dioxide memristors, ferroelectric memristor, spin-transfer torque magnetoresistance devices, spin memristive systems, and/or other techniques now known or later developed. It is noted that the memristor cell 110 utilizes fabrication techniques developed for flash memory. For example, many of the materials and processing facilities are similar and/or the same as those used to fabricate CMOS and flash memory devices. As such, fabrication of the memristor cell 110 is highly compatible with present chip fabrication facilities.

In an example, fabrication can proceed at lower temperatures than conventional memory systems fabrication. For example, the memristor memory 100 may be fabricated at temperatures less than 800-900° C., and in another example at temperatures of about 300-400° C.). These lower temperatures enable the memristor memory 100 to be fabricated over CMOS, control/drive electronics, and/or other circuitry, without damaging the underlying circuitry. As such, the memristor memory 100 may have a device structure implemented in an additive (e.g., stacked and/or side-by-side) configuration. Such a configuration enables multiple memory elements to be fabricated together, increasing memory density and decreasing the device footprint and associated cost.

Before continuing, it should be noted that the examples described above are provided to illustrate an example device structure and fabrication technique. These examples are not intended to be limiting. Other device structures and/or fabrication techniques may be implemented.

To understand operation of the device structure shown in FIGS. 1a-b, it is helpful to first explain the fundamental properties of memristance. If charge flows in one direction (e.g., as illustrated by arrows 160 in FIG. 1a) through the device structure, the resistance of the circuit increases. If charge flows in the opposite direction (e.g., as illustrated by arrows 165 in FIG. 1b) in the circuit, the resistance decreases.

A common analogy in electronics for a capacitor is to think of it as a bucket that stores water (i.e., the water is analogous to electrical charge). Likewise, an analogy for a resistor is to think of it as a pipe that carries water. Again, the water is analogous to electrical charge. But for a resistor, the pressure at the input of the pipe behaves similar to voltage, and the rate of flow of the water through the pipe behaves similar to electrical current. The flow of water through the pipe is faster if the pipe is shorter and/or has a larger diameter; just as with the resistor.

A similar analogy can be made for a memristor. But instead of the pipe having a fixed diameter (i.e., like the resistor in the above analogy has a fixed resistance), a memristor can be described as a type of pipe that expands or shrinks when water flows through it. If water flows through the pipe in one direction, the diameter of the pipe increases, thus enabling the water to flow faster. If water flows through the pipe in the opposite direction, the diameter of the pipe decreases, thus slowing down the flow of water. If the water pressure is turned off, the pipe will retain its most recent diameter until the water is turned back on. Thus, the pipe does not store water like a bucket (analogous to a capacitor). Instead, the memristor remembers how much water (analogous to electric charge) flowed through it.

The direction of charge flowing through the device structure is based on polarity of an electric potential across the channel 150 (e.g., a voltage applied to the electrodes 130, 135). For example, in FIG. 1a, a voltage is applied to the top (e.g., negative) terminal 130, causing charge carriers 170 (e.g., electrons) to flow toward the bottom (e.g., positive) terminal 135, in FIG. 1b, the polarity is reversed. That is, the voltage is applied to the bottom (e.g., negative) terminal 135, causing charge carriers 170 (e.g., electrons) to flow toward the top (e.g., positive) terminal 130.

The memristor memory 100 is said to have a regime of operation with an approximately linear charge-resistance relationship, as long as the time-integral of the current stays within certain bounds. That is, memristor resistance depends on the integral of the input applied to the terminals (rather than on the instantaneous value of the input as in a varistor).

If the flow of charge carriers 170 is stopped (e.g., by turning off the applied voltage), the memristor device 100 will ‘remember’ the last resistance of the circuit (e.g., a high resistance or a low resistance). When the flow of charge carriers 170 starts again (e.g., by turning on the applied voltage), the resistance of the circuit will be what it was when last active (e.g., the circuit will be in a high resistance state or a low resistance state). This resistance can be correlated, in terms of computer memory, to a high (or “1”) or a low (or “0”) memory state. Accordingly, the device structure can be used to retain bit values. Multiple devices may be implemented (e.g., as an array) to retain multiple bits or bytes in a computer memory.

Memristors are unique in the memory space, because of their ability to ‘remember’ the last state of the device (e.g., a high or low). Application of the memristor in memory systems may include, by way of non-limiting example, a type of non-volatile random access memory (NVRAM). Such a memory has useful properties, in that it does not ‘forget’ the data that is stored even after power is turned off. As such, memristor-based memory may be a strong competitor in the flash memory market.

During operation, a voltage has to be applied to the memristor device structure in order to change the current state (e.g., from a high to a low; or a low to a high). In conventional memory, the desired value is simply written to the memory address without first checking the current state of that memory address. For example, a memory array may have stored values {0,0,1,1}. If it is desired to write new data {1,1,1,1} to the same memory address as the stored values, in conventional memory these new data are simply written to the memory address. In other words, it does not matter that two of the values are already 1—all memory addresses are rewritten with the new data.

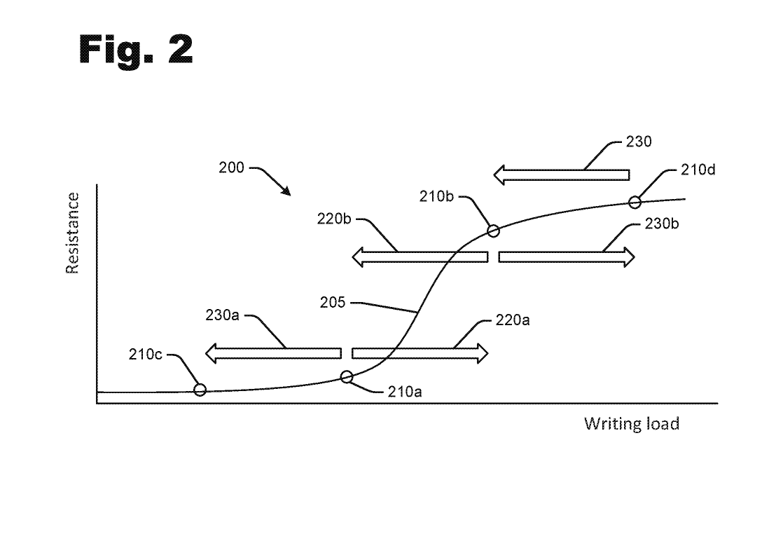

While a similar approach may be used for memristor-based memory, an electric potential has to he applied to the memristor device structure to change its state (e.g., as explained above with reference to FIGS. 1a-b). However, if the memristor device structure has already been driven to a high state (e.g., the memristor cell 110 is already storing a value “1”), and the new data includes writing a value “1” to the memristor cell, then the memristor cell is again driven high. This results in what is referred to herein as “over-driving” the memristor cell. Over-driving the memristor cell results in wider excursions from the desired or “optimal” operating conditions, as can be seen in the illustration shown in FIG. 2.

FIG. 2 is a plot 200 illustrating operational states of an example memristor memory. Plot 200 shows a resistance curve 205 as a function of the writing load, During typical operation, a memristor cell (e.g., memristor cell 110 shown in FIGS. 1a-b) is operated in the middle of the curve, as illustrated between set points 210a and 210b. This is referred to as the desired or “optimal” operating range. In this range, the memristor cell is driven to a first state (e.g., a “1” or “0”) by applying a first electric potential (e.g., charge carrier flow illustrated in the direction of arrow 160 in FIG. 1a). The memristor cell may be driven to a second, opposite state (e.g., a “0” or “1”) by applying a second, opposite electric potential (e.g., charge carrier flow illustrated in the direction of arrow 165 in FIG. 1b).

Under these operating conditions, a normal reset pulse can be used to switch the memristor cell between states. For example, if the memristor cell is storing a “1” (has a low resistance on curve 205), the state can be changed to a “0” (having a high resistance on curve 205) by applying a normal pulse 220a. Likewise, if the memristor cell is storing a “0” (has a high resistance on curve 205), the state can be changed to a “1” (having a low resistance on curve 205) by applying a normal pulse 220h.

However, if the memristor device is already storing a “0” and new data to be stored is also a “0,” then applying another net pulse 230a (e.g., to drive the memristor cell to a state of low resistance, when the memristor cell is already in a state of low resistance), may overdrive the memristor cell (e.g., to state 210c). Likewise, if the memristor device is already storing a “0” and new data to be stored is also a “0,” then applying another set pulse 230b (e.g., to drive the memristor cell to a state of high resistance, when the memristor cell is already in a state of high resistance), may overdrive the memristor cell (e.g., to state 210d). This is referred to herein as “over-driving” the memristor cell; and/or the memristor cell is said to he in an “over-written” state.

Once in an over-written state 210c or 210d, it takes a harder reset pulse (e.g., a higher voltage end/or a longer bias) to change the state of the memristor cell. For example, reset pulse 230 (e.g., a higher voltage and/or a longer bias than net pulse 220b) is needed to return the state of the memristor device back to a normal state 210b. While the memristor cell can handle being overdriven (and consequently, reset by a higher voltage and/or longer bias), over time this may take a toll on the device structure. Overdriving may lead to intermittent write failure(s), and over time may lead to outright failure of the memristor cell.

In an example, the memristor memory disclosed herein (e.g., memristor memory 100 shown in FIGS. 1a-b), reads the previously stored data in a memristor cell before writing new data to the cell. This information can be used to selectively write data to memristor cell(s), thereby reducing or altogether avoiding writing the same data into the memristor cell. As such, overdriving the memristor cell (e.g., beyond normal operating conditions) can be reduced or altogether prevented.

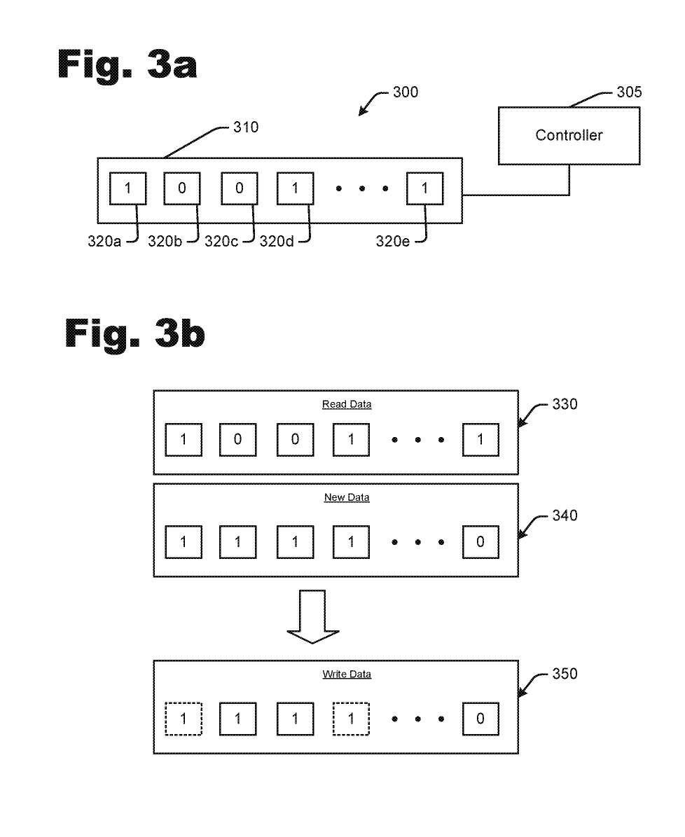

FIGS. 3a-b illustrate an example of read-before-write operations of a memristor memory 300. Example memristor memory 300 is illustrated in FIG. 3a including a controller 305 and memory array 310. The memory array 310 includes a plurality of memristor cells 320a-e.

During operation, the controller 305 may read the memristor cells 320a-e before writing new data. For example, the controller 305 may read a state of each of a plurality of memristor cells of the memristor memory to identify a subset of the plurality of memristor cells to rewrite.

In this illustration, the read data 330 in FIG. 3b includes values {1,0,0,1, . . . 1}. Also in this illustration, the new data 340 to he written includes values {1,1,1,1, . . . 0}. Two memristor cells (i.e., cell 320a and 320d in FIG. 3a) already include values corresponding to the new data 340 to be written. As such, these memristor cells (320a and 320d in this example) are not re-written. Instead, the data to be written 350 to a subset of cell(s) in the memory array 310. The data to be written 350 includes only values {−,1,1,−, . . . 0}. Memristor cells 320a and 320d are excluded from the subset, and thus not written during the write operation (as these already include the value “1”), thereby avoiding over-driving these memristor cells.

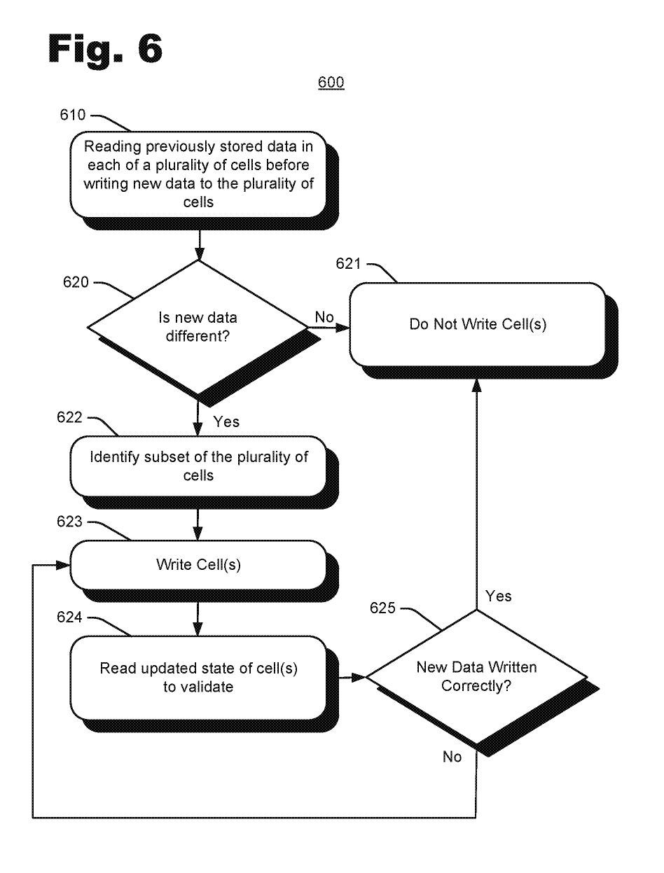

Following writing the subset of the plurality of memristor cells, the controller 305 may read an updated state of the plurality of memristor cells to validate the subset was written correctly. In an example, the controller 305 may recursively write any memristor cells in the subset that were not written correctly, as illustrated for example, in FIG. 6 discussed below.

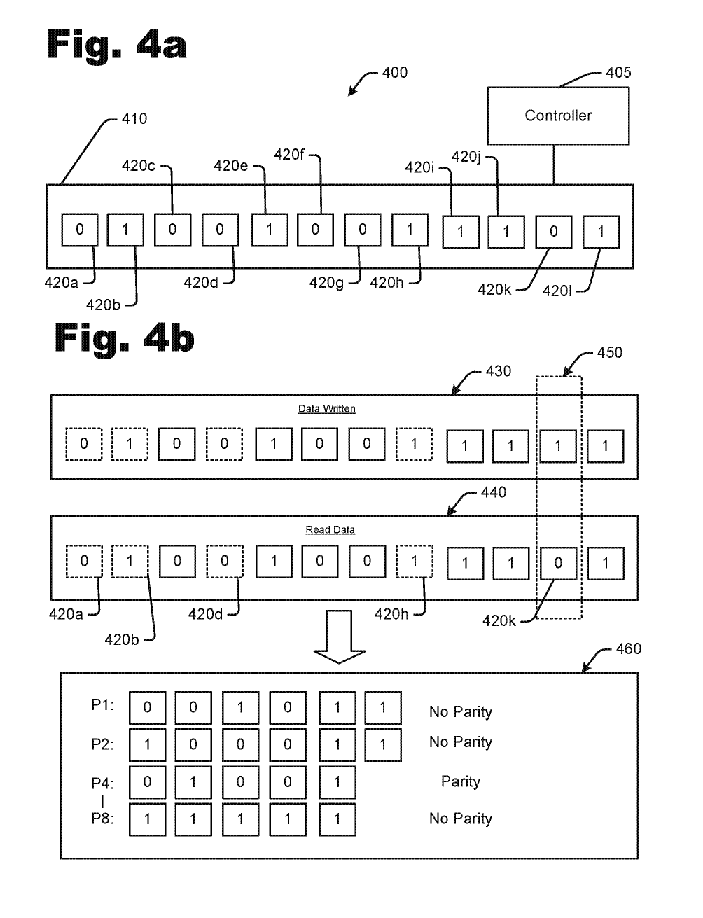

FIGS. 4a-b illustrate another example of read-before-write operations of a memristor memory 400. Example memristor memory 400 is illustrated in FIG. 4a including a controller 405 and memory array 410. The memory array 410 includes a plurality of memristor cells 420a-l. During operation, the controller 405 may read the memristor cells 420a-l.

In this example, when data is written into a memristor cell, the newly written state may be verified by reading the state of each memristor cell. Depending on the verification result, the writing sequence can be repeated if the data is not written correctly. This verification step can be performed later when the data needs to be read, for example, by employing an error-detection and correction technique. In this case no further operation is needed when writing data, because the error in writing can be detected and corrected when (and only when) the data is read later.

For purposes of illustration, consider the error correction code shown in FIG. 4b implementing parity bits. While very basic in principle, an error correction code based on parity bits can be readily understood. Of course, other more complicated error correction codes may also be implemented, as will be readily understood by one having ordinary skill in the art after becoming familiar with the teachings herein.

The data written to the memristor memory 400 is illustrated by block 430. The parity bits are illustrated with dashed lines, and include data written to memristor cells 420a, 420b, 420d, and 420h. After writing the data to memristor memory 400, the controller 405 reads back the data illustrated by block 440. It is noted that the data read back includes an error in memristor cell 420k (i.e., a “0” is read back when a “1” had been written), as highlighted by box 450 in FIG. 4b.

The controller 405 determines that this error can be corrected using an error correction code (ECC). That is, when the memristor cells are read back at a later time and parity bits P1, P2, P4, and P8 are checked, the parity bits P1, P2, and P8 do not exhibit a parity error. Hence, the controller 405 can readily determine that the eleventh memristor cell 420k has an incorrect bit (i.e., P1+P2+P8=P11). It is noted that this examples implies the code used is a truncated Hamming code; although the disclosure herein is not limited to any particular type of code. Knowing the identity of the memristor cell 420k enables this value to be corrected when the data are read out. That is, the error correction code enables the data will be corrected to a value “1” for bit position 11.

It is noted that the controller 405 does not actually change the value written to memristor cell 420k. Instead, the controller 405 recognizes that there is an error in the data written to memristor memory 400, but that the data can be corrected when it is read out, using the error correction code. That is, after a write operation, the controller 405 reads a state of each of the memristor cells 420a-l. Next, the number of switching failures is determined. In this illustration, one switching failure occurred in memristor cell 420k. The controller 405 verifies that a number of switching failures in the memristor cells 420a-e is less than a number that can be corrected by an error correction code. In this illustration, the controller 405 verifies that the single switching failure in memristor cell 420k can be corrected using the parity error correction code. As such, the controller 405 does not rewrite the data in memristor cell 420k. In an example, the controller 405 only rewrites erroneous memristor cells if the number of switching failures is larger than what can be corrected by the error correction code. In another example, memristor cells may be rewritten even when the number of errors can be corrected by the ECC, but the number of errors is within a range (e.g., satisfies a re-write threshold) such that preemptive correction is warranted.

It is noted that any suitable error correction code may be implemented with the techniques described herein. The example error correction code described with reference to FIGS. 4a-b has been simplified to better illustrate operation of the memristor memory disclosed herein. However, more complex error correction codes may be implemented based on any of a variety of design considerations.

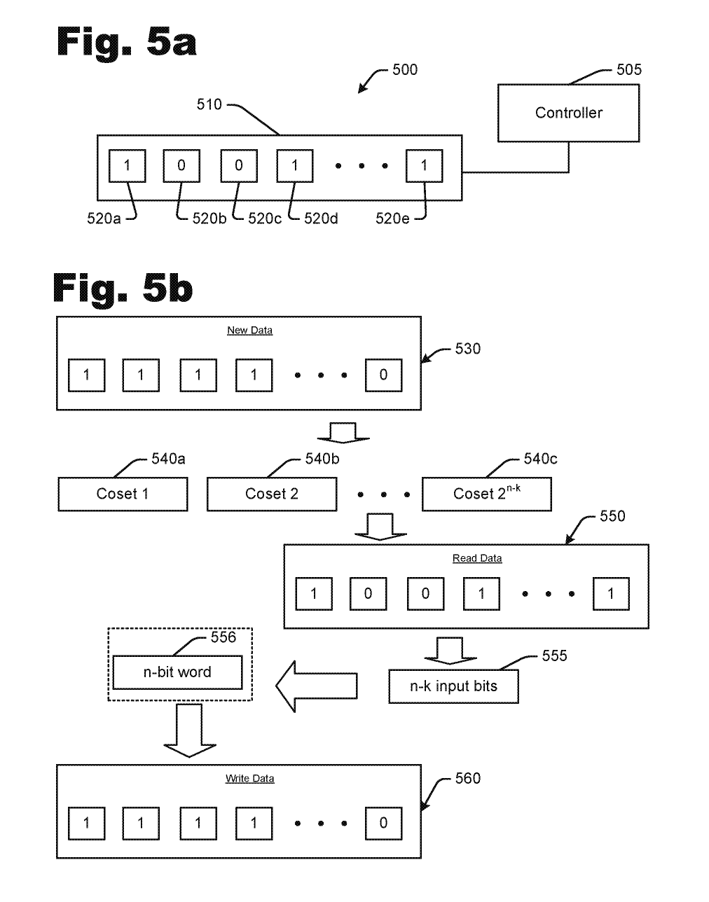

FIGS. 5a-b illustrate another example of read-before-write operations of a memristor memory 500. Example memristor memory 500 is illustrated in FIG. 5a including a controller 505 and memory array 510. The memory array 510 includes a plurality of memristor cells 520a-e. During operation, the controller 505 may read the memristor cells 520a-e.

This example illustrates the use of data coding techniques that constrain the number of memristor cells 520a-e that can change during an over-write. An example coding technique is based on cosets of linear covering codes. A linear covering code with block length n, rate k, and covering radius r is a linear code (defined by a parity check matrix H) that has the property that any n-bit word can be obtained from some valid codeword by flipping at most r bits of that codeword. Any coset of a linear covering code is also a covering code with the same rate and covering radius. In this illustration, there are 2^{n-k} cosets 540a-c.

Given such a code and its cosets 540a-c, the constrained overwrite process proceeds as follows. The controller 505 reads the previously stored n-bit word (represented by block 550) stored in the memristor cells 520a-e. The new data to be stored (represented by block 530) is represented as (n-k) bits. Hence the code is redundant (i.e., n-k bits are stored in n memristor cells) and the (n-k) bits 555 correspond to one of the 2^{n-k} cosets 540a-c of the linear covering code.

By the covering properties, there is an n-bit word 556 in this coset, one of the cosets 540a-c, that differs in r or fewer positions from the previously stored n-bit word. This will be the new word that will be stored in the corresponding memristor cells and it follows that at most r memristor cells will have to be changed. That is, the selected new word for the input data indicated coset results in limiting the number of bits stored in the memristor memory that have to be rewritten. In other words, the existing state(s) of memristor cells can be preserved to a larger extent, while only re-writing those memory cells that need to be changed.

Input data 530 is thus encoded into a word in the coset (e.g., coset 540b in FIG. 5b) to which it corresponds and is written (represented by block 560) to the memristor memory 510. In an example, the coset that is indicated or mapped to by any given n-k input data bits can be the one that yields the input data bits upon multiplication of any n-bit word in the coset by the parity check matrix H of the code. The input data can be recovered from the stored word it is encoded into by inverting the mapping from data word to coset used during encoding. For the stated example mapping, the product of the parity check matrix H with the n-bit stored word recovers the input data bits that were mapped to the coset of this stored word. This product is also sometimes called the syndrome of the n-bit word, Of course, any suitable mapping between input data bits and cosets may be used.

It is noted that in an example, codes that constrain the number of memristor cell changes can be made more robust to errors by using an error correction code (ECC) to redundantly select the coset. This use of an ECC is different than explained above with reference to FIGS. 4a-b. That is, this use of an ECC reduces errors during write constrained write operations. The data to be encoded will necessarily then have fewer than (n-k) bits, to account for the additional redundancy.

It is also noted that using the covering code technique to constrain the number of memristor cells that change, tends to work best when the cost in power of a memristor cell read is smaller than that of a memristor cell write. For purposes of illustration, suppose the ratio of the cost of a memristor cell read to that of a memristor cell write is “c,” and the cost of a write is “w.” An uncoded system incurs an average cost of cw+w/2 per cell for a read-write cycle, where in the write phase it is assumed that on average only half of the memristor cells will change and will need to be overwritten.

An optimistic rough estimate of the blow-up redundancy factor (ratio of encoded word length to uncoded word) needed to constrain to at most a p-fraction of memristor cells changing (covering radius=np) for some fraction p<1, is 1/H(p), where H(p)=−p log₂ p−(1-p)log₂ (1-p), is known as the binary entropy function. Therefore, the average cost for a corresponding coded system can be estimated as (cw+pw)/H(p).

This function can be optimized over p for any value of c. The smaller the value of c, the larger will be the factor by which the optimal code system reduces the overall cost of the read-write cycle. It is noted that practical covering codes may have somewhat smaller improvements, because the 1/H(p) factor is an optimistic theoretical estimate.

FIG. 6 is a flow chart illustrating example read-before-write operations 600 which may be implemented by a memristor memory. In this example, operation 610 includes reading previously stored data in a plurality of memristor cells of the memristor memory, before writing any new data to the plurality of memristor cells. A determination 620 is made whether the new data is different than data already stored in the memristor cell (e.g., based on a memristor cell-by-memristor cell comparison).

If the new data is not different, then at block 621 the new data does not need to be written to the memristor cell. For example, if the new data is a “1” and the memristor cell already contains a “1”, then the memristor cell does not need to be rewritten to a state of “1”.

If the new data is different, then operation 622 includes identifying a subset of the plurality of memristor cells that are to be written. For example, if the new data is a “1” and the memristor cell contains a “0”, then the memristor cell needs to be changed by driving the memristor cell to state of “1.” The subset includes the memristor cell(s) that need to be changed. Operation 623 includes writing the new data to the subset of memristor cell(s).

Operation 624 includes reading the updated state of the cell(s) to validate that the new data has been written correctly. In an example, each of the plurality of cells may be read again, e.g., to validate the word being written. In another example, only those cell(s) which were written are read in the validating operation 624. A determination 625 is made and if the cell(s) contain the correct data value or state, then the cell(s) do not need to be written again, as indicated by returning to operation 621. If the cell(s) do not contain the correct data value or state, then the cell(s) may be written again, as indicated by returning to operation 623.

It is noted that the operations shown in FIG. 6 may be iterative and may be implemented on a cell-by-cell basis and/or a plurality of cells at a time.

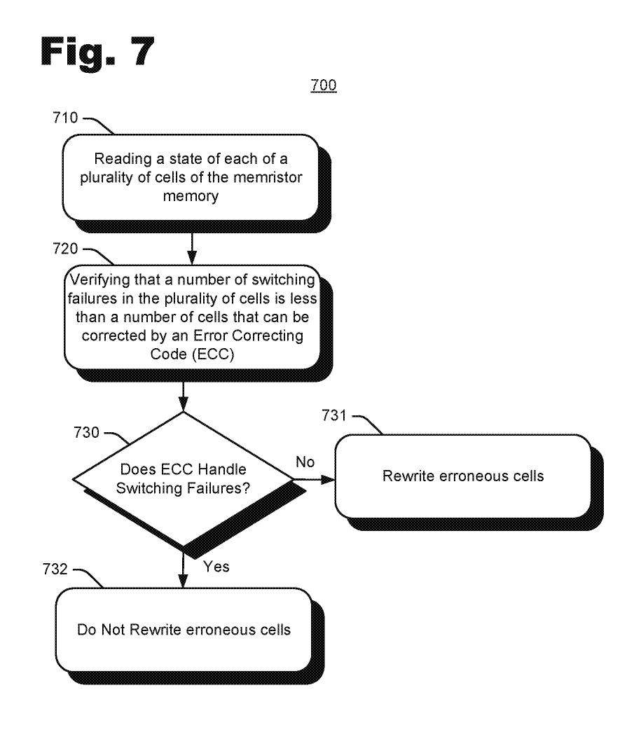

FIG. 7 is a flow chart illustrating example verification operations 700 using an error correction code. In this example, newly written data may be verified immediately after the newly written data is written to the plurality of memristor cells. Erroneous memristor cells are only rewritten if the number of switching failures is larger (or within a threshold, as noted above) than what can be corrected by the error correction code. In FIG. 7, operation 710 includes reading a state of each of a plurality of memristor cells of the memristor memory. Operation 720 includes verifying that a number of switching failures in the plurality of memristor cells. A determination 730 is made whether the switching failures can be corrected by an error correction code. If the switching failures cannot be handled by the ECC (e.g., are larger than or outside of a threshold), then in operation 731 the erroneous memristor cells are rewritten. If the switching failures can be handled by the ECC (e.g., are less than or within a threshold), then the memristor cells do not need to be rewritten as illustrated by block 732.

FIG. 8 is a flow chart illustrating example operations 800 to constrain a number of memristor cells that can change during overwrite. In this example, operation 810 includes constraining a number of the plurality of memristor cells that can change in an overwrite. For example, the constrained number of the plurality of memristor cells is based on data coding (e.g., on cosets of linear covering codes), as illustrated by block 815. Operation 820 includes reading a previously stored n-bit word from the memristor memory. Operation 830 includes representing the new data to be stored as a corresponding coset of a linear covering model. In operation 840, the new data represented in the coset is written to the memristor memory.

The operations shown and described herein are provided to illustrate example implementations. It is noted that the operations are not limited to the ordering shown. Still other operations may also be implemented.

It is noted that the memristor memory and operations described above help extend the life of individual memristor cells, while further helping to ensure minimal error rates and native endurance. When used as part of an error detection and correction scheme, the operations provide a predictable writing duration. That is, the operations include one reading sequence and an optional writing sequence, but without unnecessarily re-writing the memristor cells. That is, correcting/re-writing is only performed when the data is needed and an error is detected.

In the cases that a single write pulse is too long to yield an acceptable switching failure rate, the error correction enhanced write-verify scheme may help reduce the average energy expended on writes. That is, power consumption may also be reduced relative to analogous schemes that read-write-and verify each bit independently.

It is noted that the examples shown and described are provided for purposes of illustration and are not intended to be limiting. Still other examples are also contemplated.

1. A memristor memory, comprising:
a memristor component having a plurality of memristor cells, each memristor cell configured to change state based on application of an electric potential; and
a controller to read the state of the plurality of memristor cells and identify a subset of the plurality of memristor cells to rewrite, the controller writing the subset of the plurality of memristor cells, and the controller reading an updated state of the plurality of memristor cells to validate the subset was written correctly.

2. The memristor memory of claim 1, wherein the controller only writes new data to a memristor cell when the new data is different than stored data read from the memristor cell.

3. The memristor memory of claim 1, wherein the controller determines whether a number of switching failures in the plurality of memristor cells is correctable using an error correction code.

4. The memristor memory of claim 3, wherein the controller rewrites erroneous memristor cells if the number of switching failures is within a predetermined range.

5. The memristor memory of claim 1, wherein the controller constrains a number of the plurality of memristor cells that can change in an overwrite.

6. The memristor memory of claim 5, wherein the constrained number of the plurality of memristor cells is based on data coding.

7. The memristor memory of claim 6, wherein the data coding is based on cosets of linear covering codes.

8. A method of controlling a memristor memory, comprising:
reading a state of each of a plurality of memristor cells of the memristor memory to identify a subset of the plurality of memristor cells to rewrite;
writing the subset of the plurality of memristor cells; and
reading an updated state of the plurality of memristor cells to validate the subset was written correctly.

9. The method of claim 8, further comprising recursively writing any memristor cells in the subset that were not written correctly.

10. The method of claim 8, further comprising determining whether a number of switching failures in the plurality of memristor cells is correctable using an error correction code, wherein erroneous memristor cells are not rewritten.

11. The method of claim 8, further comprising rewriting erroneous memristor cells if the number of switching failures is within a predetermined range.

12. The method of claim 8, further comprising identifying a memristor cell as part of the subset when new data to be written to the memristor cell is different than data already stored in the memristor cell.

13. The method of claim 8, further comprising constraining a number of the plurality of memristor cells that can change in an overwrite.

14. The method of claim 13, wherein the constrained number of the plurality of memristor cells is based on data coding.

15. The method of claim 14, wherein the data coding is based on cosets of linear covering codes.
